(19) United States
(12) Patent Application Publication
(10) Pub. No.: US 2025/0379548 A1
(43) Pub. Date: Dec. 11, 2025

(54) COUPLER-BASED MM-WAVE DOHERTY POWER AMPLIFIER

(71) Applicant: QUALCOMM INCORPORATED, San Diego, CA (US)

(72) Inventors: Maziar HEDAYATI, San Diego, CA (US); Chuan WANG, San Diego, CA (US); Kevin Hsi-Huai WANG, San Diego, CA (US)

(21) Appl. No.: 18/734,208

(22) Filed: Jun. 5, 2024

(51) Int. Cl. H03F 3/24

(52) U.S. Cl. CPC H03F 3/245; H03F 2200/09; H03F 2200/451

(57) ABSTRACT

A power amplifier (PA) output network includes a balun having a plurality of interdigitated resonators, two of the plurality of interdigitated resonators configured to receive differential output signals from a power amplifier (PA), a third one of the plurality of interdigitated resonators configured to provide a single-ended output, a fourth one of the plurality of interdigitated resonators configured to connect to a signal combiner.

### FIELD

The present disclosure relates generally to electronics, and more specifically to power amplifiers in transceivers.

### BACKGROUND

Wireless communication devices and technologies are becoming ever more prevalent as are communication systems that operate at millimeter-wave (mmW) and at near-mmW frequencies or at frequencies higher than those used for mmW. Next-generation millimeter-wave power amplifiers (PAs) may support multi-standard communication systems with wide bandwidth, complex modulation, and high energy efficiency. Most existing mmW PA architectures with power backoff (PBO) efficiency enhancement, such as Doherty and outphasing PAs, typically only support limited carrier bandwidth. Instead of lumped components, current development leads to using a 180° coupler balun structure/transmission line which can serve as an extremely wideband active load modulation network for broadband PBO efficiency enhancement, However, this comes at a cost of large area size due to the quarter-and half-wave resonators that are used in the balun. Therefore, it is desirable for a balun that can perform at these frequencies to also be compact and area-efficient.

### SUMMARY

Various implementations of systems, methods and devices within the scope of the appended claims each have several aspects, no single one of which is solely responsible for the desirable attributes described herein. Without limiting the scope of the appended claims, some prominent features are described herein.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

One aspect of the disclosure provides a power amplifier (PA) output network, including a balun having a plurality of interdigitated resonators, two of the plurality of interdigitated resonators configured to receive differential output signals from a power amplifier (PA), a third one of the plurality of interdigitated resonators configured to provide a single-ended output, a fourth one of the plurality of interdigitated resonators configured to connect to a signal combiner.

Another aspect of the disclosure provides a method for combining power amplifier (PA) outputs, including generating a first power amplifier (PA) differential output; generating a second power amplifier (PA) differential output; and combining the first PA differential output and the second PA differential output using respective first and second baluns, each balun having a plurality of interdigitated resonators, the first balun configured to receive the first PA differential output, the second balun configured to receive the second PA differential output, respective outputs of the first balun and the second balun configured to provide respective outputs to a signal combiner.

Another aspect of the disclosure provides a device for combining power amplifier (PA) outputs, including means for generating a first power amplifier (PA) differential output; means for generating a second power amplifier (PA) differential output; and means for combining the first PA differential output and the second PA differential output using respective first and second baluns, each balun having a plurality of interdigitated resonators, the first balun configured to receive the first PA differential output, the second balun configured to receive the second PA differential output, respective outputs of the first balun and the second balun configured to provide respective outputs to a signal combiner.

### BRIEF DESCRIPTION OF THE DRAWINGS

In the figures, like reference numerals refer to like parts throughout the various views unless otherwise indicated. For reference numerals with letter character designations such as “102a” or “102b”, the letter character designations may differentiate two like parts or elements present in the same figure. Letter character designations for reference numerals may be omitted when it is intended that a reference numeral encompass all parts having the same reference numeral in all figures.

FIG. 1 is a diagram showing a wireless device communicating with a wireless communication system.

FIG. 2A is a block diagram showing a wireless device in which exemplary techniques of the present disclosure may be implemented.

FIG. 2B is a block diagram showing a wireless device in which exemplary techniques of the present disclosure may be implemented.

FIG. 2C is a block diagram showing a wireless device in which exemplary techniques of the present disclosure may be implemented.

FIG. 3 is a schematic diagram of a resonator in accordance with an exemplary embodiment of the disclosure.

FIG. 4 is a schematic diagram of a balun in accordance with an exemplary embodiment of the disclosure.

FIG. 5 is a schematic diagram of a power amplifier (PA) output circuit including exemplary embodiments of the balun of FIG. 4.

FIG. 6 is a schematic diagram of a power amplifier (PA) output circuit including an exemplary embodiment of the balun of FIG. 4 and an exemplary embodiment of the signal combiner of FIG. 5.

FIG. 7 is a layout of a portion of the Doherty output circuit of FIG. 6.

FIG. 8 is a graph showing power amplifier impedance.

FIG. 9 is a flow chart describing an example of the operation of a method for combining the output of a Doherty power amplifier. FIG. 10 is a functional block diagram of an apparatus for combining the output of a Doherty power amplifier.

### DETAILED DESCRIPTION

The word “exemplary” is used herein to mean “serving as an example, instance, or illustration.” Any aspect described herein as “exemplary” is not necessarily to be construed as preferred or advantageous over other aspects.

In an exemplary embodiment, a Doherty power amplifier (PA) output network includes a balun having interdigitated resonators for combining the outputs of the two power amplifiers. In an exemplary embodiment, the balun may include a plurality of interdigitated resonators.

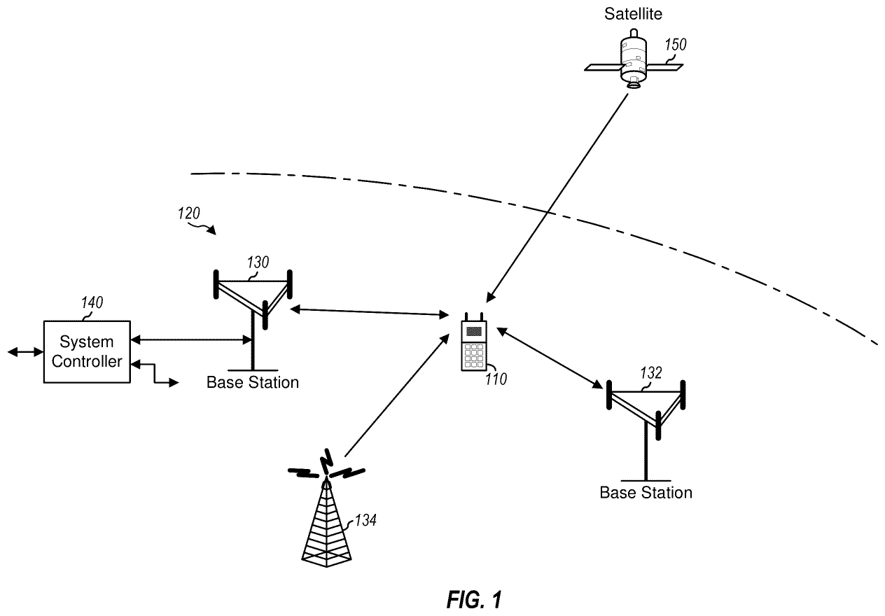

FIG. 1 is a diagram showing a wireless device 110 communicating with a wireless communication system 120. The wireless communication system 120 may be a Long Term Evolution (LTE) system, a Code Division Multiple Access (CDMA) system, a Global System for Mobile Communications (GSM) system, a wireless local area network (WLAN) system, a 5G NR (new radio) system, or some other wireless system. A CDMA system may implement Wideband CDMA (WCDMA), CDMA 1X, Evolution-Data Optimized (EVDO), Time Division Synchronous CDMA (TD-SCDMA), or some other version of CDMA. For simplicity, FIG. 1 shows wireless communication system 120 including two base stations 130 and 132 and one system controller 140. In general, a wireless communication system may include any number of base stations and any set of network entities.

The wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a tablet, a cordless phone, a medical device, an automobile, a device configured to connect to one or more other devices (for example through the internet of things), a wireless local loop (WLL) station, a Bluetooth device, etc. Wireless device 110 may communicate with wireless communication system 120. Wireless device 110 may also receive signals from broadcast stations (e.g., a broadcast station 134) and/or signals from satellites (e.g., a satellite 150 in one or more global navigation satellite systems (GNSS)), etc.). Wireless device 110 may support one or more radio technologies for wireless communication such as LTE, WCDMA, CDMA 1X, EVDO, TD-SCDMA, GSM, 802.11, 802.15, 5G, Sub6 5G, 6G, UWB, etc.

Wireless device 110 may be able to operate in a variety of communication bands including, for example, those communication bands used by LTE, WiFi, 5G or other communication bands, over a wide range of frequencies. Wireless device 110 may also be capable of communicating directly with other wireless devices without communicating through a network.

Wireless device 110 may support carrier aggregation, for example as described in one or more LTE or 5G standards. In some embodiments, a single stream of data is transmitted over multiple carriers using carrier aggregation, for example as opposed to separate carriers being used for respective data streams. In general, carrier aggregation (CA) may be categorized into two types—intra-band CA and inter-band CA. Intra-band CA refers to operation on multiple carriers within the same band. Inter-band CA refers to operation on multiple carriers in different bands.

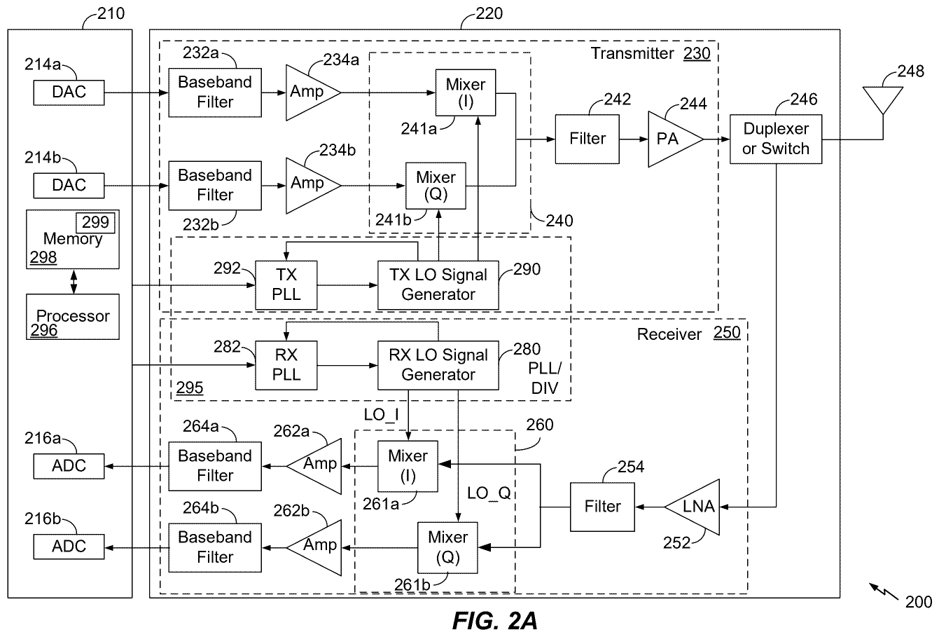

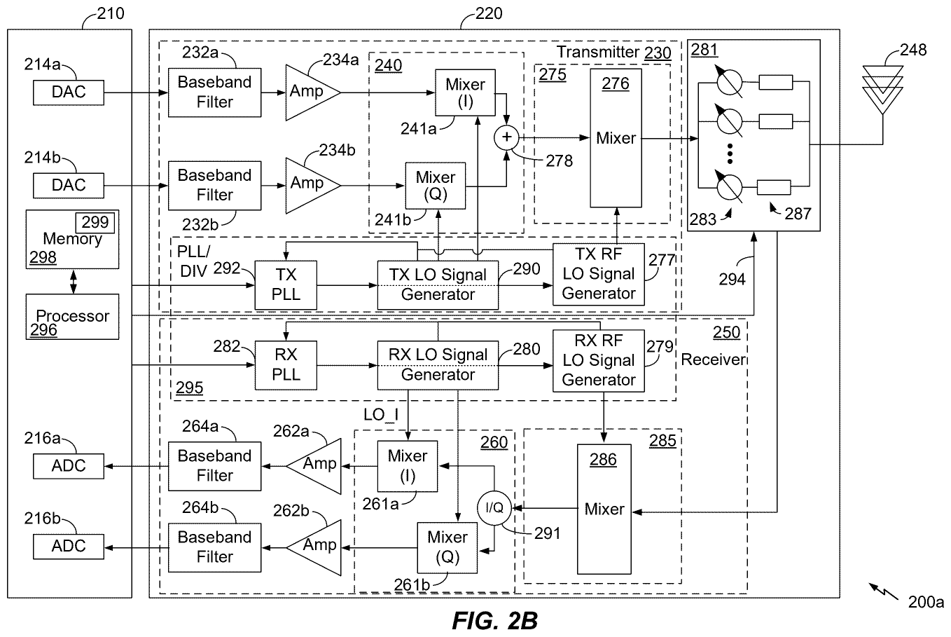

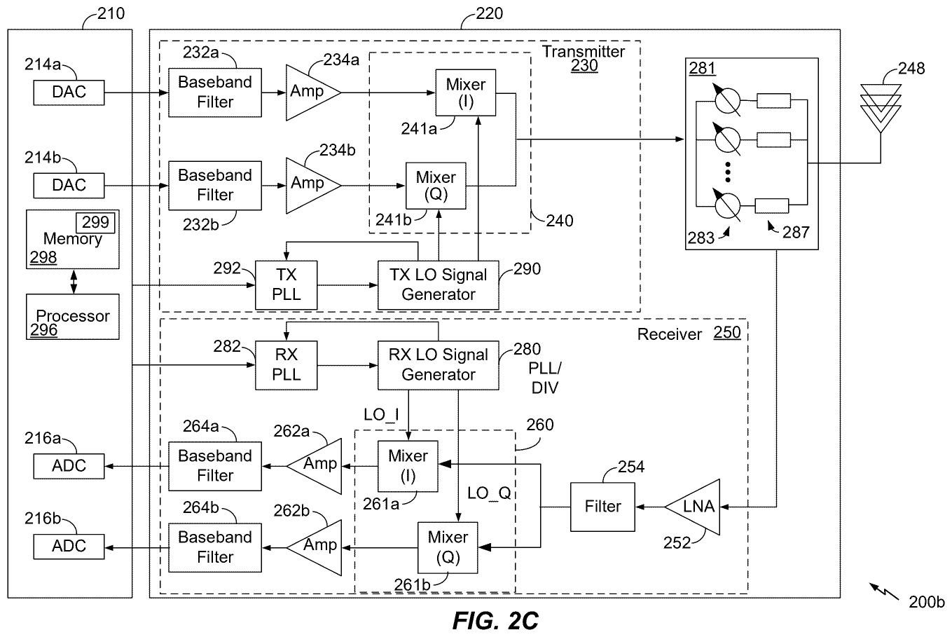

FIG. 2A is a block diagram showing a wireless device 200 in which the exemplary techniques of the present disclosure may be implemented. The wireless device 200 may, for example, be an embodiment of the wireless device 110 illustrated in FIG. 1.

FIG. 2A shows an example of a transceiver 220 having a transmitter 230 and a receiver 250. In general, the conditioning of the signals in the transmitter 230 and the receiver 250 may be performed by one or more stages of amplifier, filter, upconverter, downconverter, etc. These circuit blocks may be arranged differently from the configuration shown in FIG. 2A. Furthermore, other circuit blocks not shown in FIG. 2A may also be used to condition the signals in the transmitter 230 and receiver 250, for example phase shifters as discussed further below. Unless otherwise noted, any signal in FIG. 2A, or any other figure in the drawings, may be either single-ended or differential. Some circuit blocks in FIG. 2A may also be omitted.

In the example shown in FIG. 2A, wireless device 200 generally comprises the transceiver 220 and a data processor 210. The data processor 210 may include a processor 296 operatively coupled to a memory 298. The memory 298 may be configured to store data and program codes shown generally using reference numeral 299, and may generally comprise analog and/or digital processing components. The transceiver 220 includes a transmitter 230 and a receiver 250 that support bi-directional communication. In general, wireless device 200 may include any number of transmitters and/or receivers for any number of communication systems and frequency bands. All or a portion of the transceiver 220 may be implemented on one or more analog integrated circuits (ICs), RF ICs (RFICs), mixed-signal ICs, etc.

A transmitter or a receiver may be implemented with a super-heterodyne architecture or a direct-conversion architecture. In the super-heterodyne architecture, a signal is frequency-converted between radio frequency (RF) and baseband in multiple stages, e.g., from RF to an intermediate frequency (IF) in one stage, and then from IF to baseband in another stage for a receiver. In the direct-conversion architecture, a signal is frequency converted between RF and baseband in one stage. The super-heterodyne and direct-conversion architectures may use different circuit blocks and/or have different requirements. In the example shown in FIG. 2A, transmitter 230 and receiver 250 are implemented with the direct-conversion architecture.

In the transmit path, the data processor 210 processes data to be transmitted and provides in-phase (I) and quadrature (Q) analog output signals to the transmitter 230. In an exemplary embodiment, the data processor 210 includes digital-to-analog-converters (DAC's) 214a and 214b for converting digital signals generated by the data processor 210 into the I and Q analog output signals, e.g., I and Q output currents, for further processing. In other embodiments, the DACs 214a and 214b are included in the transceiver 220 and the data processor 210 provides data (e.g., for I and Q) to the transceiver 220 digitally.

Within the transmitter 230, lowpass filters 232a and 232b filter the I and Q analog transmit signals, respectively, to remove undesired images caused by the prior digital-to-analog conversion. Amplifiers (Amp) 234a and 234b amplify the signals from lowpass filters 232a and 232b, respectively, and provide I and Q baseband signals. An upconverter 240 having upconversion mixers 241a and 241b upconverts the I and Q baseband signals with I and Q transmit (TX) local oscillator (LO) signals from a TX LO signal generator 290 and provides an upconverted signal. A filter 242 filters the upconverted signal to remove undesired images caused by the frequency upconversion as well as noise in a receive frequency band. A power amplifier (PA) 244 amplifies the signal from filter 242 to obtain the desired output power level and provides a transmit RF signal. The transmit RF signal is routed through a duplexer or switch 246 and transmitted via an antenna 248, or alternatively it can be sent to a separate transmit antenna different from a separate receive antenna. While examples discussed herein utilize I and Q signals, those of skill in the art will understand that components of the transceiver may be configured to utilize polar modulation.

In the receive path, antenna 248 receives communication signals and provides a received RF signal, which can be routed through duplexer or switch 246 and provided to a low noise amplifier (LNA) 252. The duplexer 246 is designed to operate with a specific RX-to-TX duplexer frequency separation, such that RX signals are isolated from TX signals. Alternatively, there may be a separate transmit antenna and separate receive antenna as mentioned above, in which case RX-to-TX isolation can be achieved through the limited coupling between the two antennas. In the case of separate RX and TX antennas, the RX antenna can be coupled directly to LNA 252. The received RF signal is amplified by LNA 252 and filtered by a filter 254 to obtain a desired RF input signal. Downconversion mixers 261a and 261b in a downconverter 260 mix the output of filter 254 with I and Q receive (RX) LO signals (i.e., LO_I and LO_Q) from an RX LO signal generator 280 to generate I and Q baseband signals. The I and Q baseband signals are amplified by amplifiers 262a and 262b and further filtered by lowpass filters 264a and 264b to obtain I and Q analog input signals, which are provided to data processor 210. In the exemplary embodiment shown, the data processor 210 includes analog-to-digital-converters (ADC's) 216a and 216b for converting the analog input signals into digital signals to be further processed by the data processor 210. In some embodiments, the ADCs 216a and 216b are included in the transceiver 220 and provide data to the data processor 210 digitally.

In FIG. 2A, TX LO signal generator 290 generates the I and Q TX LO signals used for frequency upconversion, while RX LO signal generator 280 generates the I and Q RX LO signals used for frequency downconversion. Each LO signal is a periodic signal with a particular fundamental frequency. A phase locked loop (PLL) 292 receives timing information from data processor 210 and generates a control signal used to adjust the frequency and/or phase of the TX LO signals from LO signal generator 290. Similarly, a PLL 282 receives timing information from data processor 210 and generates a control signal used to adjust the frequency and/or phase of the RX LO signals from LO signal generator 280.

In an exemplary embodiment, the RX PLL 282, the TX PLL 292, the RX LO signal generator 280, and the TX LO signal generator 290 may alternatively be combined into a single LO generator circuit 295, which may include common or shared LO signal generator circuitry to provide the TX LO signals and the RX LO signals. Alternatively, separate LO generator circuits may be used to generate the TX LO signals and the RX LO signals.

Wireless device 200 may support CA and may (i) receive multiple downlink signals transmitted by one or more cells on multiple downlink carriers at different frequencies and/or (ii) transmit multiple uplink signals to one or more cells on multiple uplink carriers. Those of skill in the art will understand, however, that aspects described herein may be implemented in systems, devices, and/or architectures that do not support carrier aggregation.

Certain components of the transceiver 220 are functionally illustrated in FIG. 2A, and the configuration illustrated therein may or may not be representative of a physical device configuration in certain implementations. For example, as described above, transceiver 220 may be implemented in various integrated circuits (ICs), RF ICs (RFICs), mixed-signal ICs, etc. In some embodiments, the transceiver 220 is implemented on a substrate or board such as a printed circuit board (PCB) having various modules, chips, and/or components. For example, the power amplifier 244, the filter 242, and the duplexer 246 may be implemented in separate modules or as discrete components, while the remaining components illustrated in the transceiver 220 may be implemented in a single transceiver chip.

The power amplifier 244 may comprise one or more stages comprising, for example, driver stages, power amplifier stages, or other components, that can be configured to amplify a communication signal on one or more frequencies, in one or more frequency bands, and at one or more power levels. Depending on various factors, the power amplifier 244 can be configured to operate using one or more driver stages, one or more power amplifier stages, one or more impedance matching networks, and can be configured to provide good linearity, efficiency, or a combination of good linearity and efficiency.

In an exemplary embodiment in a super-heterodyne architecture, the filter 242, PA 244, LNA 252 and filter 254 may be implemented separately from other components in the transmitter 230 and receiver 250, and may be implemented on a millimeter wave integrated circuit. An example super-heterodyne architecture is illustrated in FIG. 2B.

FIG. 2B is a block diagram showing a wireless device in which the exemplary techniques of the present disclosure may be implemented. Certain components, for example which may be indicated by identical reference numerals, of the wireless device 200a in FIG. 2B may be configured similarly to those in the wireless device 200 shown in FIG. 2A and the description of identically numbered items in FIG. 2B will not be repeated.

The wireless device 200a is an example of a heterodyne (or superheterodyne) architecture in which the upconverter 240 and the downconverter 260 are configured to process a communication signal between baseband and an intermediate frequency (IF). For example, the upconverter 240 may be configured to provide an IF signal to an upconverter 275. In an exemplary embodiment, the upconverter 275 may comprise upconversion mixer 276. The summing function 278 of upconverter 240 combines the I and the Q outputs and provides a combined signal to the mixer 276. The combined signal may be single ended or differential. The mixer 276 is configured to receive the IF signal from the upconverter 240 and TX RF LO signals from a TX RF LO signal generator 277, and provide an upconverted RF signal to phase shift circuitry 281. While PLL 292 is illustrated in FIG. 2B as being shared by the signal generators 290, 277, a respective PLL for each signal generator may be implemented.

In an exemplary embodiment, components in the phase shift circuitry 281 may comprise one or more adjustable or variable phased array elements, and may receive one or more control signals from the data processor 210 over connection 294 and operate the adjustable or variable phased array elements based on the received control signals.

In an exemplary embodiment, the phase shift circuitry 281 comprises phase shifters 283 and phased array elements 287. Although three phase shifters 283 and three phased array elements 287 are shown for ease of illustration, the phase shift circuitry 281 may comprise more or fewer phase shifters 283 and phased array elements 287.

Each phase shifter 283 may be configured to receive the RF transmit signal from the upconverter 275, alter the phase by an amount, and provide the RF signal to a respective phased array element 287. Each phased array element 287 may comprise transmit and receive circuitry including one or more filters, amplifiers, driver amplifiers, and power amplifiers. In some embodiments, the phase shifters 283 may be incorporated within respective phased array elements 287.

The output of the phase shift circuitry 281 is provided to an antenna array 248. In an exemplary embodiment, the antenna array 248 comprises a number of antennas that typically correspond to the number of phase shifters 283 and phased array elements 287, for example such that each antenna element is coupled to a respective phased array element 287. In an exemplary embodiment, the phase shift circuitry 281 and the antenna array 248 may be referred to as a phased array.

In a receive direction, an output of the phase shift circuitry 281 is provided to a downconverter 285. In an exemplary embodiment, the downconverter 285 may comprise a downconversion mixer 286. In an exemplary embodiment, the mixer 286 downconverts the receive RF signal provided by the phase shift circuitry 281 to an IF signal according to RX RF LO signals provided by an RX RF LO signal generator 279. The I/Q generation function 291 of downconverter 260 receives the IF signal from the mixer 286 and generates I and Q signals in downconverter 260, which downconverts the IF signals to baseband, as described above. While PLL 282 is illustrated in FIG. 2B as being shared by the signal generators 280, 279, a respective PLL for each signal generator may be implemented.

In some embodiments, the upconverter 275, downconverter 285, and the phase shift circuitry 281 are implemented on a common IC. In some embodiments, the summing function 278 and the I/Q generation function 291 are implemented separate from the mixers 276 and 286 such that the mixers 276, 286 and the phase shift circuitry 281 are implemented on the common IC, but the summing function 278 and I/Q generation function 291 are not (e.g., the summing function 278 and I/Q generation function 291 are implemented in another IC coupled to the IC having the mixers 276, 286). In some embodiments, the LO signal generators 277, 279 are included in the common IC. In some embodiments in which phase shift circuitry is implemented on a common IC with 276, 286, 277, 278, 279, and/or 291, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect. For example, components of the antenna array 248 may be implemented on a substrate and coupled to an integrated circuit implementing the phase shift circuitry 281 via a flexible printed circuit or the chip may be mounted on the substrate.

In some embodiments, both the architecture illustrated in FIG. 2A and the architecture illustrated in FIG. 2B are implemented in the same device. For example, a wireless device 110 or 200 may be configured to communicate with signals having a frequency below about 7 GHz (e.g., the FR1 frequency band) using the architecture illustrated in FIG. 2A and to communicate with signals having a frequency above about 24 GHz using the architecture illustrated in FIG. 2B. In devices in which both architectures are implemented, one or more components of FIGS. 2A and 2B that are identically numbered may be shared between the two architectures. For example, both signals that have been downconverted directly to baseband from RF and signals that have been downconverted from RF to baseband via an IF stage may be filtered by the same baseband filter 264. In other embodiments, a first version of the filter 264 is included in the portion of the device which implements the architecture of FIG. 2A and a second version of the filter 264 is included in the portion of the device which implements the architecture of FIG. 2B.

FIG. 2C is a block diagram showing a wireless device in which exemplary techniques of the present disclosure may be implemented. Certain components, for example which may be indicated by identical reference numerals, of the wireless device 200b in FIG. 2C may be configured similarly to those in the wireless device 200 shown in FIG. 2A and/or the wireless device 200a shown in FIG. 2B and the description of identically numbered items in FIG. 2C will not be repeated.

The wireless device 200b in FIG. 2C incorporates the phase shift circuitry 281 (of FIG. 2B) in a direct conversion architecture, where mmW transmission signals are upconverted and downconverted between baseband and RF without the use of intermediate frequency (IF) signal conversion. Such an architecture may be referred to as a low IF (LIF), or a zero IF (ZIF) architecture. For example, the LO signals in the architecture of FIG. 2C may comprise signals at frequencies of tens of GHz. In other examples, the LO signals may be a single digit or low double digit GHz frequency (for example, when the wireless device 200b is configured for use with signals in an FR3 band) or hundreds of GHz (for example, when the wireless device 200b is configured for use with signals in a sub-THz band).

In some embodiments, the upconverter 240, downconverter 260, and the phase shift circuitry 281 are implemented on a common IC. In some embodiments, the LO signal generators 280, 290 are included in the common IC. In some embodiments, the common IC and the antenna array 248 are included in a module, which may be coupled to other components of the transceiver 220 via a connector. In some embodiments, the phase shift circuitry 281, for example, a chip on which the phase shift circuitry 281 is implemented, is coupled to the antenna array 248 by an interconnect or both are mounted to a substrate. For example, components of the antenna array 248 may be implemented on a substrate and coupled to an integrated circuit implementing the phase shift circuitry 281 via a flexible printed circuit or the integrated circuit may be mounted to an opposite side of the substrate. In some embodiments, multiple iterations of the upconverter 240 and downconverter 260 may be implemented to process multiple signals on different frequency bands.

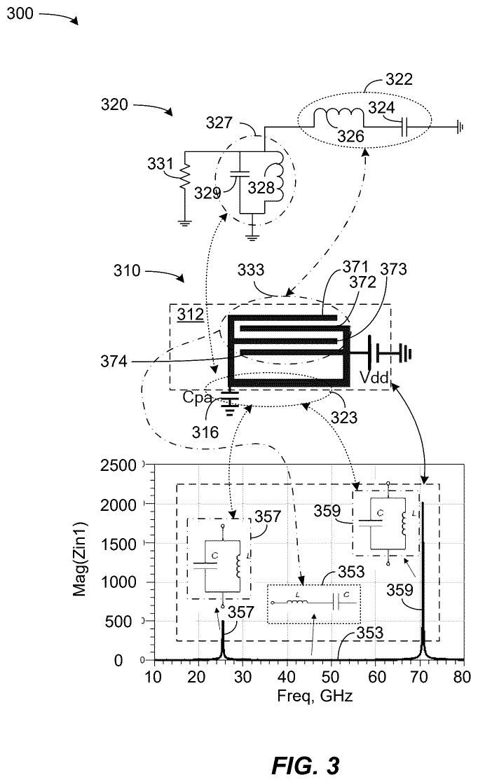

FIG. 3 is a schematic diagram 300 of a resonator 310 in accordance with an exemplary embodiment of the disclosure. Exemplary embodiments of the resonator 310 may be implemented in an output network at the output of the PA 244 of FIG. 2A, or in the phase shift circuitry 281 of FIGS. 2B and 2C. In an exemplary embodiment, the resonator 310 may comprise an interdigitated structure that is connected to a supply voltage source, Vdd, for power amplifier (PA) biasing purposes and that has a multi-resonance structure comprising series and parallel resonators, shown using reference numeral 312. A corresponding schematic diagram 320 shows a series resonator 322 that may be formed using interdigitated metal fingers and a parallel resonator 327 that may be formed as a shunt metal line. In an exemplary embodiment, the series resonator 322 may comprise a capacitance 324 and an inductance 326 connected in series. The parallel resonator 327 may comprise a capacitance 329 and an inductance 328 connected in parallel. A resistance 331 is also connected across the parallel resonator 327. The multi-resonance structure 312 shows a series resonator 333 that may be formed using interdigitated metal fingers, which corresponds to the series resonator 322; and a parallel resonator 323 formed as a shunt metal line, which together with a capacitance 316 corresponds to the parallel resonator 327. As used herein, the term interdigitated refers to an interlocking (without touching), or alternating and/or overlapping (and potentially extending from opposite sides or in opposite directions), structure of elements, such as the elements 371, 372, 373 and 374 of the series resonator 333. In an exemplary embodiment, the capacitance 316 (Cpa) refers to a parasitic capacitance of a power amplifier (PA) output (not shown in FIG. 3). This capacitance can be absorbed (or provided) in a PA output for higher order size reduction (e.g., miniaturization) of the multi-resonance structure 312.

In an exemplary embodiment, the multi resonance structure 312 exhibits a behavior which is reflected by having an input impedance of the series resonator 322 (333) as zero and having large input impedance values relative to zero of the parallel resonator 327 (323). In an exemplary embodiment, the parallel resonator 327 (323) exhibits a multiple-frequency resonance response, shown using reference numerals 357 and 359. In an exemplary embodiment, the multiple-frequency resonance responses 357 and 359 are generated by the parallel resonator 327 (323). The frequency response of the series resonator 322 (333) is shown using reference numeral 353.

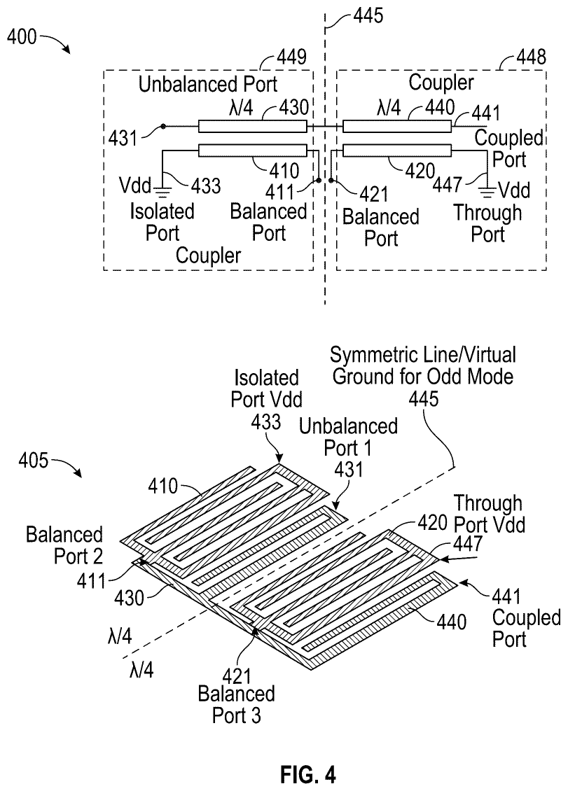

FIG. 4 is a schematic diagram 400 of a balun 405 in accordance with an exemplary embodiment of the disclosure. In an exemplary embodiment, the balun 405 may comprise resonators 410, 420, 430 and 440. In an exemplary embodiment, the resonators 430 and 440 are physically connected but they form two separate parts of two couplers 449 and 448, respectively. In an exemplary embodiment, the resonators 410, 420, 430 and 440 may be instances of the resonator 312 of FIG. 3. In an exemplary embodiment, the resonators 410 and 420 may be formed on a first layer (or plane) and the resonators 430 and 440 may be formed on a second layer (or plane), where the second layer may be at least in part below or above the first layer, or vice versa. For example, the plane of the first layer may be parallel to and spaced from the plane of the second layer.

In what is referred to as “odd-mode” circuit operation, the currents and voltages applied by a differential signal to a balanced input at port 411 and port 421 are equal in magnitude and opposite in polarity. Therefore, a symmetric line between the resonators 430 and 440 can be considered as a virtual ground as is shown using reference numeral 445. The resonator 410 and the resonator 430 form a coupler 449. The symmetric line/virtual ground 445 also electrically divides the resonator 430 from the resonator 440. In the odd-mode circuit operation, the coupler 448 is connected with a short-circuited termination at the through port 447 of the coupler 448 (e.g., a Vdd connection) and a short-circuited termination at the coupled port 441 of the coupler 448. This network behaves as an all-pass filter.

In what is referred to as “even-mode” circuit operation, the structure behaves like a coupled line with a short-circuited termination at the through port 447 (Vdd connection) and an open-circuit termination at the coupled port 441. Therefore, this network acts as an all-stop filter that blocks the signal propagation from input to output at all frequencies. A side of the resonator 410 opposite the balanced port 411 is connected to Vdd (ground) and is referred to as the isolated port 433, and a side of the resonator 420 opposite the balanced port 421 is connected to Vdd (ground) at connection 447. The even-mode may comprise a common mode.

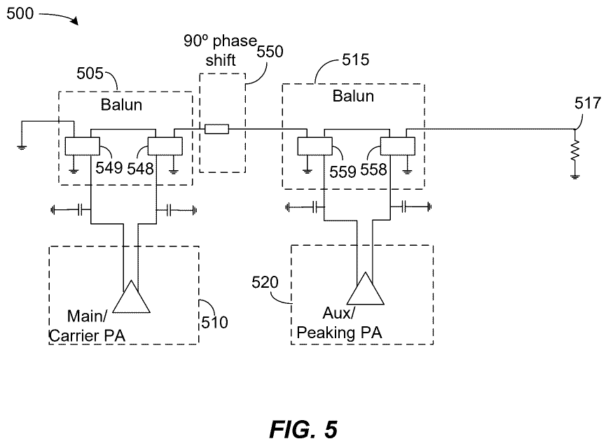

FIG. 5 is a schematic diagram of a power amplifier (PA) output circuit 500 including exemplary embodiments of the balun of FIG. 4. In an exemplary embodiment, the PA output circuit 500 shows a Doherty PA structure having a main (or carrier) PA 510 and an auxiliary (or peaking) PA 520. A differential output of the main PA 510 is provided to a balun 505 and a differential output of the auxiliary PA 520 is provided to a balun 515. The balun 505 and the balun 515 are examples of the balun 405 of FIG. 4. For example, the coupler 448 and the coupler 449 in FIG. 4 are shown as the coupler 548 and the coupler 549 in FIG. 5. Similarly, the coupler 558 and the coupler 559 are examples of the coupler 448 and the coupler 449 of FIG. 4. The single-ended output of the balun 505 and the single-ended output of the balun 515 are provided to a signal combiner 550. The signal combiner 550 ensures that a 90° phase shift is imparted between the signals from the balun 505 and the balun 515 because in some embodiments, the balun 505 and the balun 515 might not provide the desired 90 degree phase delay between the output of the main PA 510 and the output of the auxiliary PA 520. The output of the circuit 500 is provided at node 517. For example, the node 517 may be coupled to an antenna, e.g., through a bump transition on an integrated circuit. In some examples, elements that provide an interface between the bump transition, the PA output circuit 500, and receive elements (e.g., an LNA) are coupled to the node 517. The architecture shown in the circuit 500 is referred to as a “series-combined” Doherty power amplifier structure.

The concept of load modulation plays an important role in such a series-combined Doherty power amplifier structure. Load modulation involves dynamically manipulating the load impedance of the main (carrier) PA 510 and auxiliary (peaking) PA 520, enabling them to work efficiently across varying output power levels. By optimizing the load conditions, load modulation enhances overall power efficiency, linearity, and spectral performance. This technique addresses the trade-off between efficiency and linearity, which is characteristic of traditional Doherty amplifiers. As a result, a series-combined Doherty amplifier structure may achieve improved signal transmission quality, reduced distortion, and better spectral purity, making them valuable components in modern wireless communication systems. In an exemplary embodiment, a series-combined Doherty amplifier structure such as that shown in FIG. 5 combines the power output (voltage) of the main (carrier) PA 510 and the power output (voltage) of the auxiliary (peaking) PA 520 so that a combined output appears at the output 517.

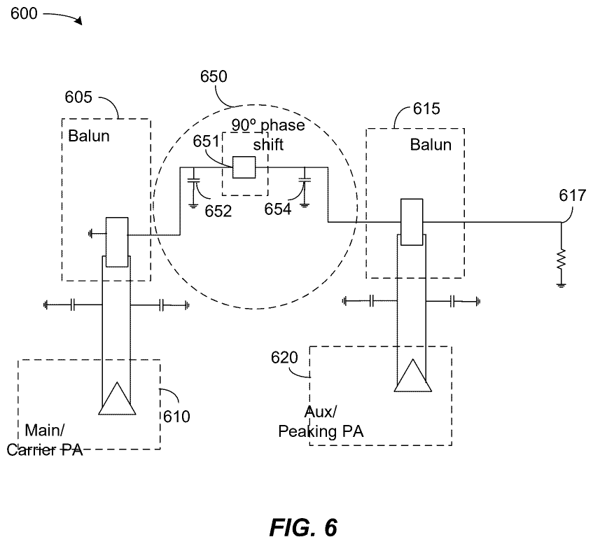

FIG. 6 is a schematic diagram of a power amplifier (PA) output circuit 600 including an exemplary embodiment of the balun of FIG. 4 and an exemplary embodiment of the signal combiner of FIG. 5. In an exemplary embodiment, the PA output circuit 600 shows a Doherty PA structure having a main (or carrier) PA 610 and an auxiliary (or peaking) PA 620. A differential output of the main PA 610 is provided to a balun 605 and a differential output of the auxiliary PA 620 is provided to a balun 615. The balun 605 and the balun 615 are examples of the balun 405 of FIG. 4. FIG. 6 also includes an exemplary embodiment of a signal combiner 550 of FIG. 5, implemented in FIG. 6 as a transmission line. In some embodiments, the balun 605 and the balun 615 might not provide the desired 90 degree phase delay between the output of the main PA 610 and the output of the auxiliary PA 620, leading to significant efficiency reduction in the main PA 610 due to increased output impedance load in the auxiliary path. To address this, an embedded transmission line 650 may be used between the single-ended output of the balun 605 and the single-ended output of the balun 615 to ensure the desired 90 degree phase difference between the output of the main PA 610 and the output of the auxiliary PA 620. In an exemplary embodiment, the embedded transmission line 650 includes a 90 degree phase shift element 651, a capacitance 652 and a capacitance 654. In an exemplary embodiment, the capacitance 652 and the capacitance 654 absorb part of the inductance of the transmission line 650, thus allowing the transmission line 650 between the balun 605 and the balun 615 to be shorter than the transmission line associated with the signal combiner 550 of FIG. 5. In an exemplary embodiment, the 90 degree phase shift element 651 may be implemented as an interconnect transmission line that may be part of the transmission line 650.

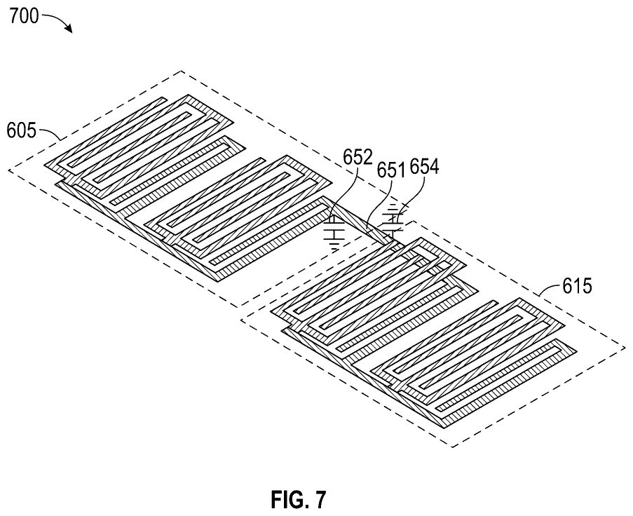

FIG. 7 is a layout 700 of a portion of the Doherty output circuit 600 of FIG. 6. The output circuit 700 comprises two baluns 605 and 615, includes the capacitance 652 and the capacitance 654, and includes the interconnect transmission line 651.

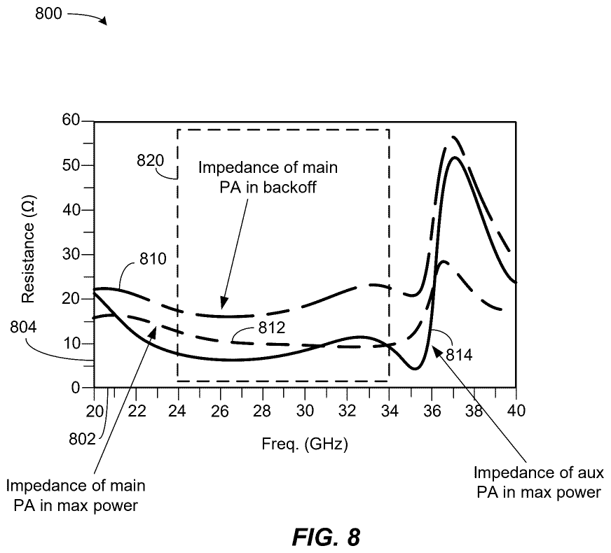

FIG. 8 is a graph 800 showing power amplifier impedance. The horizontal axis 802 represents frequency in gigahertz (GHz) and the vertical axis 804 represents impedance in ohms (Ω). The trace 810 shows impedance of the main power amplifier in backoff power, the trace 812 shows the impedance of the main power amplifier at maximum power, and the trace 814 shows the impedance of the auxiliary power amplifier at max power. The impedance of the traces 810, 812 and 814 is within a relatively small range in the frequency range of approximately 24 GHz to approximately 34 GHz as shown in the dotted box 820.

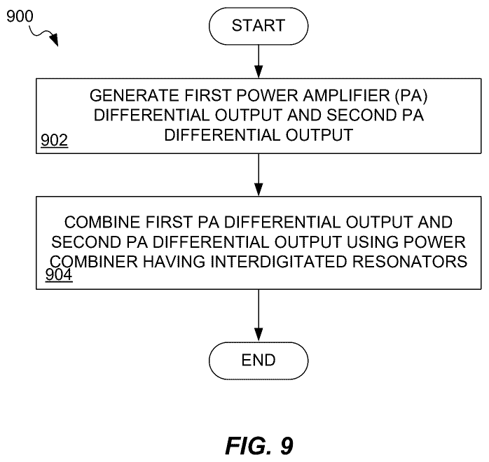

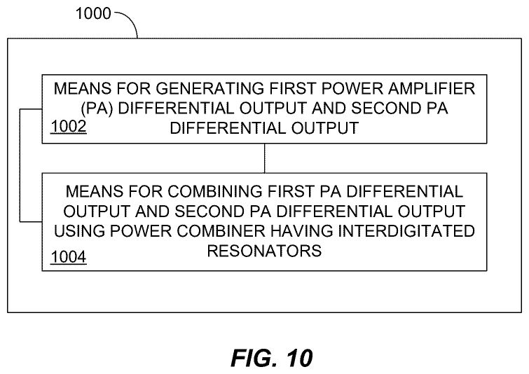

FIG. 9 is a flow chart 900 describing an example of the operation of a method for combining the output of a Doherty power amplifier. The blocks in the method 900 can be performed in or out of the order shown, and in some embodiments, can be performed at least in part in parallel.

In block 902, a first power amplifier (PA) (carrier PA) provides a differential output and a second PA (peaking PA) provides a differential output. For example, the main (carrier) PA 510 provides a differential output to the balun 505 and the auxiliary (peaking) PA 520 provides a differential output to the balun 515.

In block 904, the first PA differential output and the second PA differential output are combined using a power combiner having a plurality of interdigitated resonators. For example, two of the plurality of interdigitated resonators are configured to receive the first PA differential output and second PA differential output. A third one of the plurality of interdigitated resonators is configured to provide a single-ended (unbalanced) output, and a fourth one of the plurality of interdigitated resonators is configured to connect to the 90° phase shift element 550.

FIG. 10 is a functional block diagram of an apparatus 1000 for combining the output of a Doherty power amplifier. The apparatus 1000 comprises means 1002 for generating a first power amplifier (PA) (carrier PA) differential output and a second PA (peaking PA) differential output. In certain embodiment, the means 1002 for generating a first power amplifier (PA) (carrier PA) differential output and a second PA (peaking PA) differential output can be configured to perform one or more of the functions described in operation block 902 of method 900 (FIG. 9). In an exemplary embodiment, the means 1002 for generating a first power amplifier (PA) (carrier PA) differential output and a second PA (peaking PA) differential output may comprise the main (carrier) PA 510 configured to provide a differential output to the balun 505 and the auxiliary (peaking) PA 520 configured to provide a differential output to the balun 515.

The apparatus 1000 may also comprise means 1004 for combining the first PA differential output and the second PA differential output using a power combiner having a plurality of interdigitated resonators. In certain embodiment, the means 1004 for combining the first PA differential output and the second PA differential output using a power combiner having a plurality of interdigitated resonators can be configured to perform one or more of the functions described in operation block 904 of method 900 (FIG. 9). In an exemplary embodiment, the means 1004 for combining the first PA differential output and the second PA differential output using a power combiner having a plurality of interdigitated resonators may comprise two of the plurality of interdigitated resonators being configured to receive the first PA differential output and second PA differential output. A third one of the plurality of interdigitated resonators may be configured to provide a single-ended (unbalanced) output, and a fourth one of the plurality of interdigitated resonators may configured to connect to the 90° phase shift element 550.

Implementation examples are described in the following numbered clauses:
1. A power amplifier (PA) output network, comprising: a balun having a plurality of interdigitated resonators, two of the plurality of interdigitated resonators configured to receive differential output signals from a power amplifier (PA), a third one of the plurality of interdigitated resonators configured to provide a single-ended output, a fourth one of the plurality of interdigitated resonators configured to connect to a signal combiner.
2. The output network of clause 1, wherein each of the plurality of interdigitated resonators comprises a parallel resonator and a series resonator.
3. The output network of any of clauses 1 or 2, wherein the balun comprises a first balun connected between a main power amplifier (PA) and the signal combiner, and wherein the output network further comprises a second balun connected between an auxiliary power amplifier (PA) and the signal combiner, and the signal combiner imparts a 90° phase shift with respect to an output of the main PA and the auxiliary PA.
4. The output network of clause 3, wherein the signal combiner comprises a transmission line and further comprises a first capacitance and a second capacitance connected to the transmission line, where the first capacitance and the second capacitance absorb a portion of an inductance of the transmission line.
5. The output network of any of clauses 1 through 4, wherein when operating in “odd-mode”, currents and voltages applied by the differential output signals to a balanced input at a first balanced port and at a second balanced port are equal in magnitude and opposite in polarity so that a symmetric line forms between the two of the plurality of interdigitated resonators configured to receive the differential output signals.
6. The output network of any of clauses 1 through 5, wherein when operating in “even-mode”, the balun behaves like a coupled line with a short-circuited termination at a through port and an open-circuit termination at a coupled port.
7. The output network of clause 2, wherein the series resonator comprises interdigitated metal conductors.
8. The output network of clause 2, wherein the parallel resonator comprises a shunt metal line.
9. The output network of clause 2, wherein the parallel resonator provides a multiple-frequency resonance response.
10. A method for combining power amplifier (PA) outputs, comprising: generating a first power amplifier (PA) differential output; generating a second power amplifier (PA) differential output; and combining the first PA differential output and the second PA differential output using respective first and second baluns, each balun having a plurality of interdigitated resonators, the first balun configured to receive the first PA differential output, the second balun configured to receive the second PA differential output, respective outputs of the first balun and the second balun configured to provide respective outputs to a signal combiner.
11. The method of clause 10, further comprising implementing each of the plurality of interdigitated resonators as a parallel resonator and a series resonator.
12. The method of any of clauses 10 through 11, further comprising the signal combiner imparting a 90° phase shift with respect to an output of the first PA and the second PA.
13. The method of clause 12, further comprising implementing the signal combiner as a transmission line and further comprising connecting a first capacitance and a second capacitance connected to the transmission line, where the first capacitance and the second capacitance absorb a portion of an inductance of the transmission line.
14. The method of any of clauses 10 through 13, wherein when operating in “odd-mode”, currents and voltages applied by the differential output signals to a balanced input at a first balanced port and a second balanced port of each of the first and second baluns are equal in magnitude and opposite in polarity so that a symmetric line forms between two of the plurality of interdigitated resonators configured to receive the differential output signals.
15. The method of any of clauses 10 through 14, further comprising when operating in “even-mode”, the first balun and the second balun behave like a coupled line with a short-circuited termination at a through port and an open-circuit termination at a coupled port.
16. A device for combining power amplifier (PA) outputs, comprising: means for generating a first power amplifier (PA) differential output; means for generating a second power amplifier (PA) differential output; and means for combining the first PA differential output and the second PA differential output using respective first and second baluns, each balun having a plurality of interdigitated resonators, the first balun configured to receive the first PA differential output, the second balun configured to receive the second PA differential output, respective outputs of the first balun and the second balun configured to provide respective outputs to a signal combiner.
17. The device of clause 16, further comprising means for implementing each of the plurality of interdigitated resonators as a parallel resonator and a series resonator.
18. The device of any of clauses 16 through 17, further comprising means for imparting a 90° phase shift with respect to an output of the first PA and the second PA.
19. The device of any of clauses 16 through 18, further comprising means for implementing the signal combiner as a transmission line and further comprising means for connecting a first capacitance and a second capacitance to the transmission line, where the first capacitance and the second capacitance absorb a portion of an inductance of the transmission line.
20. The device of any of clauses 16 through 19, further comprising means for operating in “odd-mode”, whereby currents and voltages applied by the differential output signals to a balanced input at a first balanced port and a second balanced port of each of the first and second baluns are equal in magnitude and opposite in polarity so that a symmetric line forms between two of the plurality of interdigitated resonators configured to receive the differential output signals.
21. The device of any of clauses 16 through 20, further comprising means for operating in “even-mode”, whereby the first balun and the second balun behave like a coupled line with a short-circuited termination at a through port and an open-circuit termination at a coupled port.
22. An output network for a power amplifier (PA), comprising: a first power amplifier (PA) configured to provide a first differential output; a second power amplifier (PA) configured to provide a second differential output; a first balun connected to the first PA and configured to receive the first differential output; a second balun connected to the second PA and configured to receive the second differential output; and a phase shift element connected to the first balun and the second balun, the phase shift element configured to combine an output of the first balun and an output of the second balun.
23. The output network of clause 22, wherein each of the first balun and the second balun comprises a plurality of interdigitated resonators, two of the plurality of interdigitated resonators configured to receive either the first or second differential output, a third one of the plurality of interdigitated resonators configured to provide a single-ended output, a fourth one of the plurality of interdigitated resonators configured to connect to the phase shift element.
24. The output network of any of clauses 22 through 23, wherein the phase shift element comprises a transmission line and further comprises a first capacitance and a second capacitance connected to the transmission line, where the first capacitance and the second capacitance absorb a portion of an inductance of the transmission line.
25. The output network of any of clauses 22 through 24, wherein each of the plurality of interdigitated resonators comprises a parallel resonator and a series resonator.
26. The output network of clause 25, wherein the series resonator comprises interdigitated metal conductors.
27. The output network of clause 25, wherein the parallel resonator comprises a shunt metal line.
28. The output network of clause 25, wherein the parallel resonator provides a multiple-frequency resonance response.

The circuit architecture described herein described herein may be implemented on one or more ICs, analog ICs, RFICs, mixed-signal ICs, ASICs, printed circuit boards (PCBs), electronic devices, etc. The circuit architecture described herein may also be fabricated with various IC process technologies such as complementary metal oxide semiconductor (CMOS), N-channel MOS (NMOS), P-channel MOS (PMOS), bipolar junction transistor (BJT), bipolar-CMOS (BiCMOS), silicon germanium (SiGe), gallium arsenide (GaAs), heterojunction bipolar transistors (HBTs), high electron mobility transistors (HEMTs), silicon-on-insulator (SOI), etc.

An apparatus implementing the circuit described herein may be a stand-alone device or may be part of a larger device. A device may be (i) a stand-alone IC, (ii) a set of one or more ICs that may include memory ICs for storing data and/or instructions, (iii) an RFIC such as an RF receiver (RFR) or an RF transmitter/receiver (RTR), (iv) an ASIC such as a mobile station modem (MSM), (v) a module that may be embedded within other devices, (vi) a receiver, cellular phone, wireless device, handset, or mobile unit, (vii) etc.

Although selected aspects have been illustrated and described in detail, it will be understood that various substitutions and alterations may be made therein without departing from the spirit and scope of the present invention, as defined by the following claims.

What is claimed is:

1. A power amplifier (PA) output network, comprising:
a balun having a plurality of interdigitated resonators, two of the plurality of interdigitated resonators configured to receive differential output signals from a power amplifier (PA), a third one of the plurality of interdigitated resonators configured to provide a single-ended output, a fourth one of the plurality of interdigitated resonators configured to connect to a signal combiner.

2. The output network of claim 1, wherein each of the plurality of interdigitated resonators comprises a parallel resonator and a series resonator.

3. The output network of claim 1, wherein the balun comprises a first balun connected between a main power amplifier (PA) and the signal combiner, and wherein the output network further comprises a second balun connected between an auxiliary power amplifier (PA) and the signal combiner, and the signal combiner imparts a 90° phase shift with respect to an output of the main PA and the auxiliary PA.

4. The output network of claim 3, wherein the signal combiner comprises a transmission line and further comprises a first capacitance and a second capacitance connected to the transmission line, where the first capacitance and the second capacitance absorb a portion of an inductance of the transmission line.

5. The output network of claim 1, wherein when operating in “odd-mode”, currents and voltages applied by the differential output signals to a balanced input at a first balanced port and at a second balanced port are equal in magnitude and opposite in polarity so that a symmetric line forms between the two of the plurality of interdigitated resonators configured to receive the differential output signals.

6. The output network of claim 1, wherein when operating in “even-mode”, the balun behaves like a coupled line with a short-circuited termination at a through port and an open-circuit termination at a coupled port.

7. The output network of claim 2, wherein the series resonator comprises interdigitated metal conductors.

8. The output network of claim 2, wherein the parallel resonator comprises a shunt metal line.

9. The output network of claim 2, wherein the parallel resonator provides a multiple-frequency resonance response.

10. A method for combining power amplifier (PA) outputs, comprising:
generating a first power amplifier (PA) differential output;
generating a second power amplifier (PA) differential output; and
combining the first PA differential output and the second PA differential output using respective first and second baluns, each balun having a plurality of interdigitated resonators, the first balun configured to receive the first PA differential output, the second balun configured to receive the second PA differential output, respective outputs of the first balun and the second balun configured to provide respective outputs to a signal combiner.

11. The method of claim 10, further comprising implementing each of the plurality of interdigitated resonators as a parallel resonator and a series resonator.

12. The method of claim 10, further comprising the signal combiner imparting a 90° phase shift with respect to an output of the first PA and the second PA.

13. The method of claim 12, further comprising implementing the signal combiner as a transmission line and further comprising connecting a first capacitance and a second capacitance connected to the transmission line, where the first capacitance and the second capacitance absorb a portion of an inductance of the transmission line.

14. The method of claim 10, wherein when operating in “odd-mode”, currents and voltages applied by the differential output signals to a balanced input at a first balanced port and a second balanced port of each of the first and second baluns are equal in magnitude and opposite in polarity so that a symmetric line forms between two of the plurality of interdigitated resonators configured to receive the differential output signals.

15. The method of claim 10, further comprising when operating in “even-mode”, the first balun and the second balun behave like a coupled line with a short-circuited termination at a through port and an open-circuit termination at a coupled port.

16. A device for combining power amplifier (PA) outputs, comprising:
means for generating a first power amplifier (PA) differential output;
means for generating a second power amplifier (PA) differential output; and
means for combining the first PA differential output and the second PA differential output using respective first and second baluns, each balun having a plurality of interdigitated resonators, the first balun configured to receive the first PA differential output, the second balun configured to receive the second PA differential output, respective outputs of the first balun and the second balun configured to provide respective outputs to a signal combiner.

17. The device of claim 16, further comprising means for implementing each of the plurality of interdigitated resonators as a parallel resonator and a series resonator.

18. The device of claim 16, further comprising means for imparting a 90° phase shift with respect to an output of the first PA and the second PA.

19. The device of claim 18, further comprising means for implementing the signal combiner as a transmission line and further comprising means for connecting a first capacitance and a second capacitance to the transmission line, where the first capacitance and the second capacitance absorb a portion of an inductance of the transmission line.

20. The device of claim 19, further comprising means for operating in “odd-mode”, whereby currents and voltages applied by the differential output signals to a balanced input at a first balanced port and a second balanced port of each of the first and second baluns are equal in magnitude and opposite in polarity so that a symmetric line forms between two of the plurality of interdigitated resonators configured to receive the differential output signals.
